(19) United States
(12) Patent Application Publication
(10) Pub. No.: US 2024/0030108 A1
(43) Pub. Date: Jan. 25, 2024

(54) TRANSFER MOLDED POWER MODULES AND METHODS OF MANUFACTURE

(71) Applicant: SEMICONDUCTOR COMPONENTS INDUSTRIES, LLC, Scottsdale, AZ (US)

(72) Inventors: Jerome TEYSSEYRE, Singapore (SG); Oseob JEON, Seoul (KR); Chee Hiong CHEW, Seremban (MY); Seungwon IM, Bucheon (KR)

(73) Assignee: SEMICONDUCTOR COMPONENTS INDUSTRIES, LLC, Scottsdale, AZ (US)

(21) Appl. No.: 18/345,308

(22) Filed: Jun. 30, 2023

Related U.S. Application Data
(60) Provisional application No. 63/369,004, filed on Jul. 21, 2022.

(51) Int. Cl. H01L 23/495; H01L 25/065; H01L 23/31; H01L 21/56; H01R 12/58

(52) U.S. Cl. CPC H01L 23/49555; H01L 25/0655; H01L 23/3107; H01L 21/56; H01R 12/585

(57) ABSTRACT

In a general aspect, an electronic device assembly includes a circuit including at least one semiconductor die, and a molded body encapsulating the circuit. The molded body has a primary surface arranged in a plane and a side surface that is non-parallel with the plane. The assembly also includes a slot defined in the primary surface of the molded body, and a signal lead extending out of the side surface of the molded body. The signal lead is electrically coupled with the circuit and has a plurality of bends that include a bend of that is at least partially disposed in the slot.

### RELATED APPLICATION

This application claims priority to and the benefit of U.S. Provisional Application No. 63/369,004, filed on Jul. 21, 2022, entitled “POWER MODULE SEMICONDUCTOR PACKAGE,” the disclosure of which is incorporated by reference herein in its entirety.

### TECHNICAL FIELD

This description relates to electronic device assemblies. More specifically, this description relates to semiconductor device modules, such as power semiconductor device modules.

### BACKGROUND

Semiconductor devices (e.g., semiconductor die) can be included in package assemblies or modules, where such modules can include signal leads and power tabs that are arranged along a side surface (edge) of a molded module (e.g., a transfer molded module). Such signal leads can be L-shaped to facilitate insertion into a printed circuit board (PCB). However, during insertion, such signal leads can be deformed (pushed back) or broken. In some implementations, a guide part or tool can be used to prevent deformation or breakage. However, use of a guide part complicates integration of such modules in a corresponding system and increases total system cost.

### SUMMARY

In a general aspect, an electronic device assembly includes a circuit including at least one semiconductor die, and a molded body encapsulating the circuit. The molded body has a primary surface arranged in a plane and a side surface that is non-parallel with the plane. The assembly also includes a slot defined in the primary surface of the molded body, and a signal lead extending out of the side surface of the molded body. The signal lead is electrically coupled with the circuit and has a plurality of bends including a bend that is at least partially disposed in the slot.

Implementations can include one or more of the following features, alone or in combination. For example, the bend of the plurality of bends is a semicircular bend that is at least partially disposed in the slot. The semicircular bend can contact the slot at a proximal end of the slot and a distal end of the slot. An apex of the semicircular bend can be spaced from a bottom surface of the slot, or the apex of the semicircular bend can be in contact with a bottom surface of the slot.

The side surface can be multi-faceted, the signal lead extending of the side surface at an intersection of a first facet and a second facet.

The bend of the plurality of bends can be a first bend. The signal lead can include a first portion that extends out of the side surface and parallel to the plane of the primary surface, and a second portion that is orthogonal to the first portion. A second bend of the plurality of bends can be disposed between the first portion and the second portion. The signal lead can include a third portion that is orthogonal to the second portion and parallel to the plane of the primary surface. A third bend of the plurality of bends can be disposed between the second portion and the third portion. The signal lead can include a fourth portion that is orthogonal to the plane of the primary surface. The first bend can be disposed between the fourth portion and the third portion. The fourth portion of the signal lead can be configured for press-fit insertion in a printed circuit board, or can be configured for solder connection to a printed circuit board.

The first portion of the signal lead can be disposed on a first side of the plane of the primary surface. The third portion of the signal lead and the fourth portion of the signal lead can be disposed on a second side of the plane of the primary surface, the second side being opposite the first side.

The slot can be a first slot, the signal lead can be a first signal lead, the side surface can be a first side surface, and the molded body can further have a second side surface that is that is non-parallel with the plane of the primary surface. The assembly can include a second slot defined in the primary surface of the molded body. A second signal lead can extend out of the second side surface of the molded body. The second signal lead can be electrically coupled with the circuit and have a plurality of bends, where a bend of the plurality of bends of the second signal lead can be at least partially disposed in the second slot.

The molded body can have a third side surface that is that is non-parallel with the plane of the primary surface. The assembly can include a third slot defined in the primary surface of the molded body. A third signal lead can extend out of the third side surface of the molded body. The third signal lead can be electrically coupled with the circuit and have a plurality of bends, where a bend of the plurality of bends of the third signal lead can be at least partially disposed in the third slot.

The molded body can have a fourth side surface that is that is non-parallel with the plane of the primary surface. The assembly can include a fourth slot defined in the primary surface of the molded body. A fourth signal lead can extend out of the fourth side surface of the molded body. The fourth signal lead can be electrically coupled with the circuit and have a plurality of bends, where a bend of the plurality of bends of the fourth signal lead can be at least partially disposed in the fourth slot.

The slot can be a first slot, and the signal lead can be a first signal lead. The assembly can include a second slot defined in the primary surface of the molded body. A second signal lead can extend out of the side surface of the molded body. The second signal lead can be electrically coupled with the circuit and have a plurality of bends, a bend of the plurality of bends of the second signal lead can be at least partially disposed in the second slot.

In another general aspect, a method for forming an electronic device assembly includes producing a circuit assembly including at least one semiconductor die, electrically coupling a signal lead with the circuit assembly, and forming a molded body by encapsulating the circuit assembly in a molding compound. The molded body has a primary surface arranged in a plane, and a side surface that is non-parallel with the plane. The molded body has a slot defined in the primary surface. The signal lead extends out the side surface of the molded body. The method further includes forming a plurality of bends in the signal lead, such that a bend of the plurality of bends is at least partially disposed in the slot.

Implementations can include one or more of the following features, alone or in combination. For example, forming the bend of the plurality of bends can include forming a semicircular bend. The semicircular bend can contact the slot at a proximal end of the slot and a distal end of the slot. An apex of the semicircular bend can be spaced from a bottom surface of the slot, or the apex can be in contact with a bottom surface of the slot.

The semicircular bend can be a first bend. Forming the plurality of bends can include forming a second bend between a first portion of the signal lead that extends out of the side surface parallel to the plane of the primary surface and a second portion of the signal lead that is orthogonal to the first portion, and forming a third bend between the second portion and a third portion of the signal lead that is parallel to the plane of the primary surface. The first bend can be between disposed between the third portion and a fourth portion of the signal lead that is orthogonal to the plane of the primary surface.

### BRIEF DESCRIPTION OF THE DRAWINGS

FIGS. 1A to 1C are diagrams illustrating various views of an example semiconductor device assembly.

FIGS. 2A and 2B are diagrams illustrating cross-sectional view of the assembly of FIGS. 1A to 1C.

FIGS. 3A and 3B are diagrams illustrating various views of an example implementation of the assembly of FIGS. 1A to 1C.

FIGS. 4A and 4B are diagrams illustrating various views of another example semiconductor device assembly.

FIG. 5 is a flowchart illustrating an example method for producing a semiconductor device assembly, such as the assemblies of FIGS. 1A-1C, FIGS. 2A-2B, FIGS. 3A-3B, and/or FIGS. 4A-4B.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

This disclosure relates to packaged semiconductor device apparatuses, which can be referred to as modules, assemblies, semiconductor device modules, power semiconductor device modules, semiconductor device assemblies, etc., as well as associated methods for producing such apparatuses. The approaches illustrated and described herein can be used to implement molded (e.g., transfer molded) semiconductor device modules (e.g., half-bridge power modules in the example implementations described herein) that can overcome at least some of the drawbacks of prior approaches discussed above. While the approaches described herein are generally described for a half-bridge power module, in some implementations semiconductor device modules implementing other circuits are possible, such as, for instance, a full-bridge power module, a 3-phase half-bridge module, a multi-phase half-bridge module, etc.

In the implementations described herein, signal leads of a semiconductor assembly, e.g., that extend out of side surfaces of a molded body of the assembly, rather than being L-shaped, can have a plurality of bends. For instance, the signal leads can have respective portions that extend over a primary surface of the molded body of the assembly. Further, for a given signal lead, its bends can include a bend that is at least partially disposed in a respective slot defined in the primary surface of the molded body (e.g., in a molding compound of the assembly). In some implementations, the bend that is at least partially disposed in the slot can contact the molding compound in the slot, e.g., at proximal and distal ends of the slot and/or at a bottom surface of the slot. In some implementations, the bend that is at least partially disposed in the slot can be a semicircular bend, which can also be referred to as a U-shaped bend, a curved, an arced bend, etc. (hereafter semicircular bend). In some implementations, an apex of the semicircular bend can contact a bottom surface of the slot. In some implementations, the apex can be spaced from the bottom surface of the slot. In example implementations, the slot (and molded body) can provide structural support to the signal lead(s) during insertion of the assembly in a corresponding system, such as in a printed circuit board (PCB), a socket, etc., which can prevent bending or breaking of the signal leads.

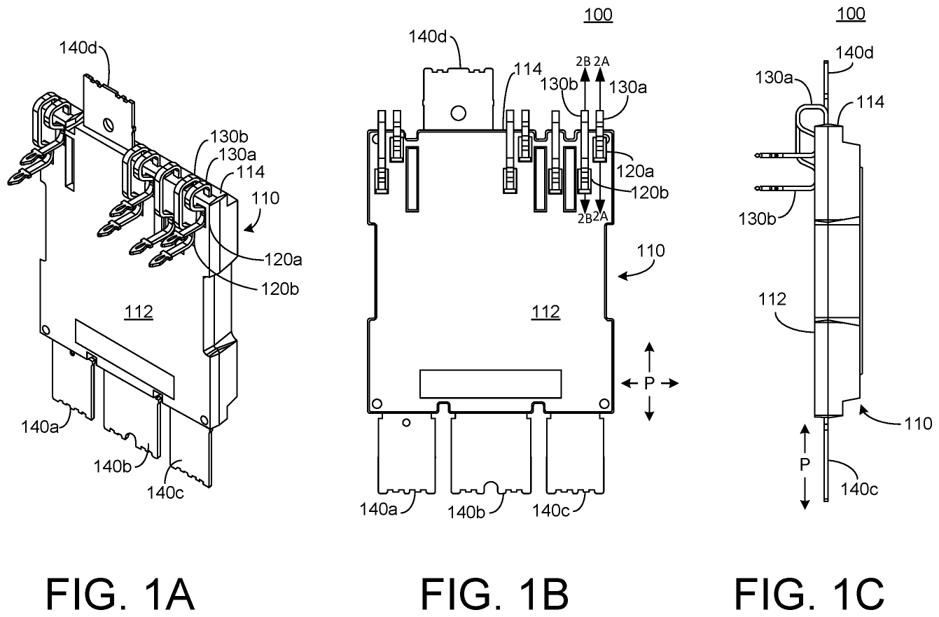

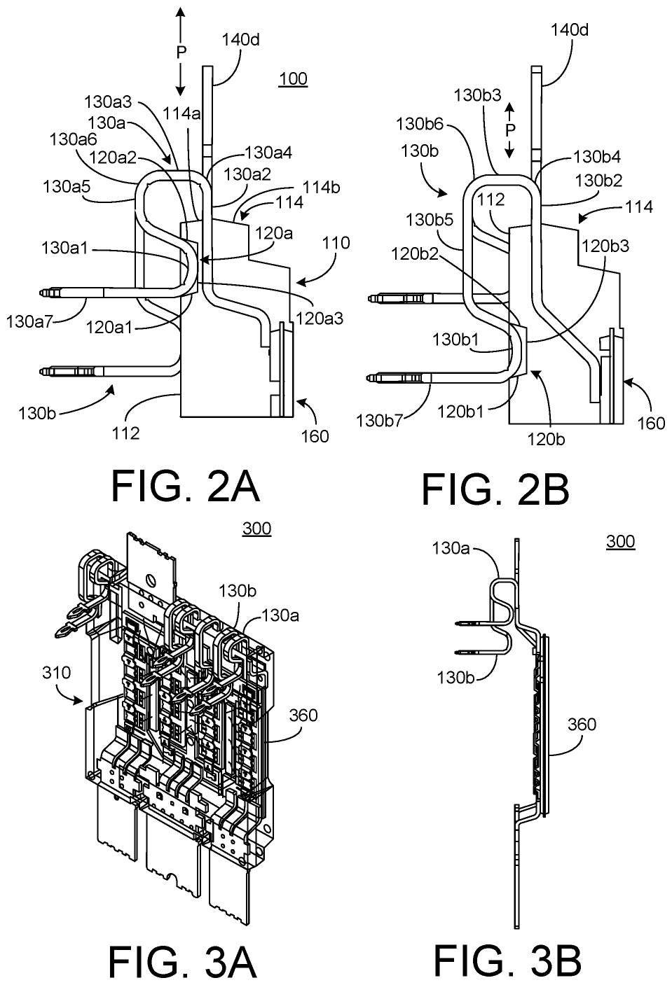

FIGS. 1A to 1C are diagrams illustrating various views of an example semiconductor device assembly 100. FIG. 1A illustrates an isometric view of the semiconductor device assembly 100, FIG. 1B illustrates a front-side view of the semiconductor device assembly 100, and FIG. 1C illustrates a side view of the semiconductor device assembly 100, e.g., from a right side of the semiconductor device assembly 100 as shown in FIG. 1B. Section line 2A-2A and section line 2B-2B shown in FIG. 1B correspond, respectively, with the cross-sectional views of FIGS. 2A and 2B, which are discussed below.

The semiconductor device assembly 100 can include a semiconductor device circuit, such as a half-bridge circuit or other circuit. The circuit of the semiconductor device assembly 100 can be encapsulated in a molded body 110. The molded body 110 can be formed from an epoxy molding compound using, e.g., a transfer molding process. In some implementations, other molding processes, such as injection molding could be used.

As shown in FIGS. 1A to 1C, the molded body 110 includes a primary surface 112 and a side surface 114. The primary surface 112 is arranged in (e.g., aligned along, parallel to and aligned within, disposed within) plane P, and the side surface 114 is non-parallel to the primary surface 112 or plane P. In some implementations, the side surface 114 can be orthogonal to the primary surface 112, or can define an angle of greater than ninety degrees and less than one-hundred and ten degrees with the primary surface 112. In some implementations, such as in the example of FIGS. 1A to 1C, the side surface 114 can be multi-faceted, e.g., having two facets with an intersection (seam, connection, peak, etc.) from which the signal leads extend out of the molded body 110.

As shown in FIGS. 1A and 1B, a plurality of slots (dents, openings, recesses, etc.) can be formed in the primary surface 112 of the molded body 110. For instance, a slot 120a and a slot 120b are referenced in FIGS. 1A and 1B. The semiconductor device assembly 100 can also include a plurality of signal leads, such as a signal lead 130a and a signal lead 130b, and a plurality of power tabs 140a, 140b, 140c and 140d. The signal leads 130a-130b, as well as the power tabs 140a-140b can be electrically coupled with the circuit of the semiconductor device assembly 100. For instance, electrical connections can be formed using direct-lead attachment to a substrate, using conductive clips, and/or using wire bonds. The power tabs 140a-140d can include negative and positive power supply tabs, as well as an output power tab (e.g., for a half-bridge circuit, or other circuit of the semiconductor device assembly 100).

As illustrated in FIGS. 1A to 1C, the signal lead 130a and the signal lead 130b (as well as other signal leads of the semiconductor device assembly 100) each has a portion that extends out of, and away from, the side surface 114, e.g., parallel to the plane P. Each of the signal leads includes a plurality of bends, such that respective portions extend over the primary surface 112 of the molded body 110. Further, the signal lead 130a and the signal lead 130b each includes a bend of its plurality of bends that is at least partially disposed in a respective slot. For instance, the signal lead 130a includes a semicircular bend that is partially disposed in the slot 120a, while the signal lead 130b includes a semicircular bend that is partially disposed in the slot 120b. In the arrangement shown in FIGS. 1A-1C (as well as in FIGS. 2A and 2B), the molded body 110 and the slots (e.g., 120a and 120b) provide mechanical support of the signal leads (e.g., 130a and 130b) during insertion of the semiconductor device assembly 100 in a corresponding system, such as insertion of portions of the signal leads that are orthogonal to the plane P of the primary surface 112. This mechanical support helps prevent bending or breaking of the signal leads. In this example, the other signal leads of the semiconductor device assembly 100 are similarly configured.

As noted above, FIGS. 2A and 2B are diagrams illustrating cross-sectional view of the assembly of FIGS. 1A to 1C. FIG. 2A is a cross-sectional view of the semiconductor device assembly 100 corresponding with the section line 2A-2A in FIG. 1B, while FIG. 2B is a cross-sectional view of the semiconductor device assembly 100 corresponding with the section line 2B-2B in FIG. 1B. Specifically, FIG. 2A illustrates a cross-section through the slot 120a and the signal lead 130a, and FIG. 2B illustrates a cross-section through the slot 120b and the signal lead 130b.

As shown in FIG. 2A, the slot 120a includes a proximal end 120a1, a distal end 120a2, and a bottom surface 120a3. The signal lead 130a includes a semicircular bend 130a1 that is partially disposed in the slot 120a. As shown in FIG. 2A, the semicircular bend 103a1 is in contact with the proximal end 120a1 of the slot 120a and the distal end 120a2 of the slot 120a. In this example, an apex of the semicircular bend 120a1 is in contact with the bottom surface 120a3 of the slot 120a. As can be seen in FIG. 2A (as well as in FIGS. 1A-1C), the location of the semicircular bends of the signal leads 130a and 130b are staggered in this example (e.g., are different distances from the side surface 114). Such staggering can allow for achieving a desired spacing between respective portions of the signal leads that are orthogonal to the primary surface 112 of the molded body 110, e.g., portions of the signal leads configured for attachment, e.g., soldering, press-fit insertion, etc., of the semiconductor device assembly 100 in a corresponding system.

As illustrated in FIG. 2A, the signal lead 130a extends out of the side surface 114 of the molded body 110. In this example, the signal lead 130a (and other signals leads of the semiconductor device assembly 100) extend out of the side surface 114 at an intersection between a facet 114a and a facet 114b of the side surface 114. For instance, a portion 130a2 of the signal lead 130a extends out of the side surface 114 parallel to the plane P of the primary surface 112. A portion 130a3 of the signal lead 130a extends orthogonal to the portion 130a2, with a bend 130a4 being disposed between, e.g., connecting, the portion 130a2 and the portion 130a3. As further shown in FIG. 2A, a portion 130a5 of the signal lead 130a extends orthogonal to the portion 130a3, e.g., parallel to the plane P of the primary surface 112, with a bend 130a6 being disposed between, e.g., connecting, the portion 130a3 and the portion 130a5. The signal lead 130a further includes a portion 130a7 that is orthogonal to the plane P of the primary surface 112. The semicircular bend 130a1 is disposed between, e.g., connects, the portion 130a5 and the portion 130a7 of the signal lead 130a. In some implementations, the portion 130a7 of the signal lead 130a can be configured for press-fit insertion, e.g., into a PCB, a socket, etc. In some implementations, the portion 130a7 of the signal lead 130a can be configured for solder connection, e.g., with a PCB, etc. In the example of FIG. 2A, the portion 130a2 of the signal lead 130a is disposed on, and spaced from a first side of the plane P of the primary surface 112, while the portion 130a5 of the signal lead 130a is disposed on, and spaced from a second side of the primary surface 112 that is opposite the first side.

As further shown in FIG. 2A, the signal lead 130a can be electrically coupled with a circuit assembly 160 of the semiconductor device assembly 100. For instance, a portion of the signal lead 130a disposed within the molded body 110 can be electrically coupled with the circuit assembly 160. In this example, the circuit assembly 160 can include a direct-bonded metal (DBM) substrate. The circuit assembly 160 can further include a plurality of semiconductor die that are disposed on the substrate, along with one or more conductive clips and/or one or more wire bonds used for interconnecting elements of a circuit implemented by the circuit assembly 160.

Referring now to FIG. 2B, the slot 120b includes a proximal end 120b1, a distal end 120b2, and a bottom surface 120b3. The signal lead 130b includes a semicircular bend 130b1 that is partially disposed in the slot 120b. As shown in FIG. 2B, the semicircular bend 130b1 is in contact with the proximal end 120b1 of the slot 120b and the distal end 120b2 of the slot 120a. In this example, an apex of the semicircular bend 120a1 is spaced from, e.g., not in contact with, the bottom surface 120b3 of the slot 120b.

As illustrated in FIG. 2B, the signal lead 130b extends out of the side surface 114 of the molded body 110. For instance, a portion 130b2 of the signal lead 130b extends out of the side surface 114 parallel to the plane P of the primary surface 112. A portion 130b3 of the signal lead 130b extends orthogonal to the portion 130b2, with a bend 130b4 being disposed between, e.g., connecting, the portion 130b2 and the portion 130b3. As further shown in FIG. 2B, a portion 130b5 of the signal lead 130b extends orthogonal to the portion 130b3, e.g., parallel to the plane P of the primary surface 112, with a bend 130b6 being disposed between, e.g., connecting, the portion 130b3 and the portion 130b5. The signal lead 130a further includes a portion 130b7 that is orthogonal to the plane P of the primary surface 112. The semicircular bend 130b1 is disposed between, e.g., connects, the portion 130b5 and the portion 130b7 of the signal lead 130b. In some implementations, as with the portion 130a7, the portion 130b7 of the signal lead 130b can be configured for press-fit insertion, e.g., into a PCB, a socket, etc. In some implementations, the portion 130b7 of the signal lead 130b can be configured for solder connection, e.g., with a PCB, etc. As with the signal lead 130a, as shown in FIG. 2B, the portion 130b2 of the signal lead 130b is disposed on, and spaced from a first side of the plane P of the primary surface 112, while the portion 130b5 of the signal lead 130b is disposed on, and spaced from a second side of the primary surface 112 that is opposite the first side.

As further shown in FIG. 2B, as with the signal lead 130a, the signal lead 130b can be electrically coupled with the circuit assembly 160 of the semiconductor device assembly 100. For instance, a portion of the signal lead 130b disposed within the molded body 110 can be electrically coupled with the circuit assembly 160, such as using the approaches described herein.

FIGS. 3A and 3B are diagrams illustrating various views of an example semiconductor device assembly 300 that can be an implementation of the semiconductor device assembly 100 of FIGS. 1A to 1C and FIGS. 2A to 2B. FIG. 3A is an isometric view of the semiconductor device assembly 300 corresponding with the isometric view of the semiconductor device assembly 100 in FIG. 1A.

In FIG. 3A, the semiconductor device assembly 300 is shown with a molding compound of a molded body 310 being illustrated as transparent, to illustrate the arrangement of a circuit assembly 360 within the molded body 310, and the arrangement of the signal lead 130a and the signal lead 130b. In this example, the circuit assembly 360 can include a DBM substrate, such as a direct-bonded copper (DBC) substrate. A plurality of semiconductor die can be disposed on the substrate, e.g., high-side transistor(s) and low-side transistor(s) of a half-bridge circuit. The circuit assembly 360 can further include a plurality of conductive clips and/or a plurality of wire bonds, that are used to implement electrical connections of the circuit of the circuit assembly 360.

FIG. 3B is a side view of the semiconductor device assembly 300 corresponding with the side view of the semiconductor device assembly 100 of FIG. 1C. In FIG. 3C, the semiconductor device assembly 300 is illustrated without the molding compound of the molded body 310, again, as with FIG. 3A, to show the arrangement of the circuit assembly 360 in the semiconductor device assembly 300, e.g., arrangement relative to the signal lead 130a and the signal lead 130b.

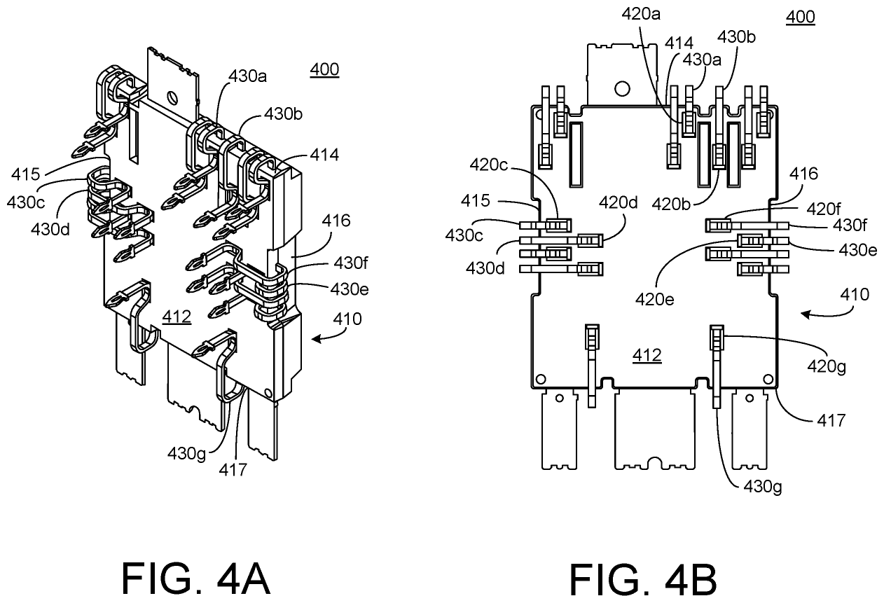

FIGS. 4A and 4B are diagrams illustrating various views of another example semiconductor device assembly 400. FIG. 4A illustrates an isometric view of the semiconductor device assembly 400, while FIG. 4B illustrates a front side view of the semiconductor device assembly 400. As compared to the semiconductor device assembly 100, the semiconductor device assembly 400 includes signal leads, such as the signal lead 130a and the signal lead 140b, extending out of each four side surfaces of a molded body 410 of the semiconductor device assembly 400, e.g., a side surface 414, a side surface 415, a side surface 416, and a side surface 417.

While not all signal leads of the semiconductor device assembly 400 are specifically referenced in FIGS. 4A and 4B, as illustrated, a signal lead 430a and a signal lead 430b extend out of the side surface 414 of the molded body 410. A signal lead 430c and a signal lead 430d extend out of the side surface 415. A signal lead 430e and a signal lead 430f extend out of the side surface 416. A signal lead 430g extends out of the side surface 417. In this example, the signal leads of the semiconductor device assembly 400 can include a plurality of bends, such as described above with respect to the signal lead 130a and the signal lead 130b. For instance, the signals leads of the semiconductor device assembly 400 can have respective semicircular bends that are at least partially disposed in corresponding slots, e.g., slots 420a, 420b, 430c, 420d, 420e, 420f and 420g, defined in a primary surface 412 of the molded body 410, as well as other bends to configure the signal leads as shown in FIGS. 4A and 4B. Though not specifically referenced, the semiconductor device assembly 400 further includes a plurality of power tabs, e.g., at least one positive power tab (e.g., a power supply voltage potential), at least one negative power tab (e.g., electrical ground), and at least one output power tab.

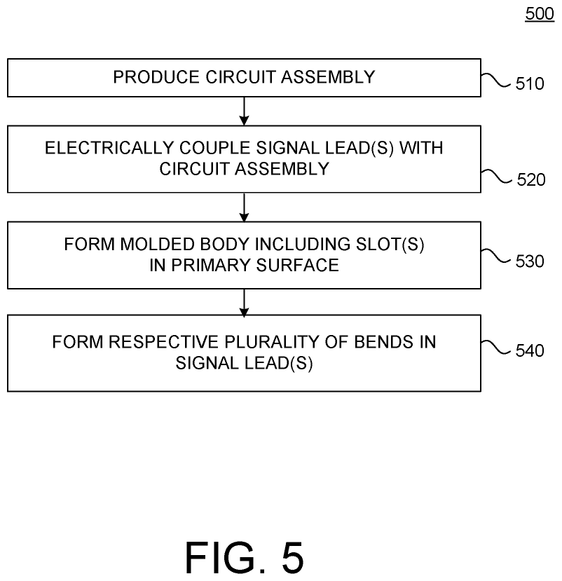

FIG. 5 is a flowchart illustrating an example method 500 for producing a semiconductor device assembly, such as the assemblies of FIGS. 1A-1C, FIGS. 2A-2B, FIGS. 3A-3B, and FIGS. 4A-4B. At block 510, the method 500 includes producing a circuit assembly, such as the circuit assembly 160 of FIGS. 2A and 2B, or the circuit assembly 360 of the FIGS. 3A and 3B. At block 520, the method includes electrically coupling at least one signal lead with a circuit of the circuit assembly, such as using direct-lead attachment to a substrate, one or more conductive clips and/or one or more wire bonds. At block 520 each signal lead, as well as corresponding power tabs, can be included in a planar, single leadframe body. At block 530, the method 500 includes forming a molded body, such as the molded body 110 of the semiconductor device assembly 100, the molded body 310 of the semiconductor device assembly 300, or the molded body 410 of the semiconductor device assembly 400. Forming the molded body at block 530 can include defining slots in a primary surface of the molded body, such as the slots described with respect to FIGS. 1A-1C, 2A-2B, 3A-3B and 4A-4b. At block 540, the method 500 includes forming a plurality of bends in each of the signal leads, e.g., to configure the signal leads as described herein, e.g., to have a bend at least partially disposed in a respective slot in a primary surface the molded body, such as the signal lead 130a and the slot 120a, and/or the signal lead 130b and the slot 120b. The bends can be formed in the signal leads, using stamping, metal working tools (die), etc.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An electronic device assembly comprising:
a circuit including at least one semiconductor die;
a molded body encapsulating the circuit, the molded body having a primary surface arranged in a plane and a side surface that is non-parallel with the plane;
a slot defined in the primary surface of the molded body; and
a signal lead extending out of the side surface of the molded body, the signal lead being electrically coupled with the circuit and having a plurality of bends, a bend of the plurality of bends being at least partially disposed in the slot.

2. The electronic device assembly of claim 1, wherein the bend of the plurality of bends is a semicircular bend.

3. The electronic device assembly of claim 2, wherein the semicircular bend contacts the slot:
at a proximal end of the slot; and
at a distal end of the slot.

4. The electronic device assembly of claim 3, wherein an apex of the semicircular bend is spaced from a bottom surface of the slot.

5. The electronic device assembly of claim 3, wherein an apex of the semicircular bend is in contact with a bottom surface of the slot.

6. The electronic device assembly of claim 1, wherein the side surface is multi-faceted, the signal lead extending out the side surface at an intersection of a first facet and a second facet.

7. The electronic device assembly of claim 1, wherein the bend of the plurality of bends is a first bend,
the signal lead including:
a first portion that extends out of the side surface parallel to the plane of the primary surface;
a second portion that is orthogonal to the first portion, a second bend of the plurality of bends being disposed between the first portion and the second portion;
a third portion that is orthogonal to the second portion and parallel to the plane of the primary surface, a third bend of the plurality of bends being disposed between the second portion and the third portion; and
a fourth portion that is orthogonal to the plane of the primary surface, the first bend being disposed between the fourth portion and the third portion.

8. The electronic device assembly of claim 7, wherein the fourth portion of the signal lead is configured for press-fit insertion.

9. The electronic device assembly of claim 7, wherein the fourth portion of the signal lead is configured for solder connection.

10. The electronic device assembly of claim 7, wherein:
the first portion of the signal lead is disposed on a first side of the plane of the primary surface; and
the third portion of the signal lead and the fourth portion of the signal lead are disposed on a second side of the plane of the primary surface, the second side being opposite the first side.

11. The electronic device assembly of claim 1, wherein the slot is a first slot, the signal lead is a first signal lead, the side surface is a first side surface, and the molded body further has a second side surface that is that is non-parallel with the plane of the primary surface,
the electronic device assembly further comprising:
a second slot defined in the primary surface of the molded body; and
a second signal lead extending out of the second side surface of the molded body, the second signal lead being electrically coupled with the circuit and having a plurality of bends, a bend of the plurality of bends of the second signal lead being at least partially disposed in the second slot.

12. The electronic device assembly of claim 11, wherein the molded body further has a third side surface that is that is non-parallel with the plane of the primary surface,
the electronic device assembly further comprising:
a third slot defined in the primary surface of the molded body; and
a third signal lead extending out of the third side surface of the molded body, the third signal lead being electrically coupled with the circuit and having a plurality of bends, a bend of the plurality of bends of the third signal lead being at least partially disposed in the third slot.

13. The electronic device assembly of claim 12, wherein the molded body further has a fourth side surface that is that is non-parallel with the plane of the primary surface,
the electronic device assembly further comprising:
a fourth slot defined in the primary surface of the molded body; and
a fourth signal lead extending out of the fourth side surface of the molded body, the fourth signal lead being electrically coupled with the circuit and having a plurality of bends, a bend of the plurality of bends of the fourth signal lead being at least partially disposed in the fourth slot.

14. The electronic device assembly of claim 1, wherein the slot is a first slot, and the signal lead is a first signal lead,
the electronic device assembly further comprising:
a second slot defined in the primary surface of the molded body; and
a second signal lead extending out of the side surface of the molded body, the second signal lead being electrically coupled with the circuit and having a plurality of bends, a bend of the plurality of bends of the second signal lead being at least partially disposed in the second slot.

15. A method for forming an electronic device assembly comprising:
producing a circuit assembly including at least one semiconductor die;
electrically coupling a signal lead with the circuit assembly;
forming a molded body by encapsulating the circuit assembly in a molding compound, the molded body having a primary surface arranged in a plane and a side surface that is non-parallel with the plane, the molded body having a slot defined in the primary surface, the signal lead extending out the side surface of the molded body; and
forming a plurality of bends in the signal lead, such that a bend of the plurality of bends is at least partially disposed in the slot.

16. The method of claim 15, wherein forming the bend of the plurality of bends includes forming a semicircular bend.

17. The method of claim 16, wherein forming the plurality of bends includes forming the plurality of bends such that the semicircular bend contacts the slot at a proximal end of the slot and a distal end of the slot.

18. The method of claim 17, wherein forming the plurality of bends includes forming the plurality of bends such that an apex of the semicircular bend is spaced from a bottom surface of the slot.

19. The method of claim 17, wherein a forming the plurality of bends includes forming the plurality of bends such that apex of the semicircular bend is in contact with a bottom surface of the slot.

20. The method of claim 16, wherein the semicircular bend is a first bend, and forming the plurality of bends further includes:
forming a second bend between a first portion of the signal lead that extends out of the side surface parallel to the plane of the primary surface and a second portion of the signal lead that is orthogonal to the first portion; and
forming a third bend between the second portion and a third portion of the signal lead that is parallel to the plane of the primary surface,
the first bend being between disposed between the third portion and a fourth portion of the signal lead that is orthogonal to the plane of the primary surface.
